(19) United States
(12) Patent Application Publication
(10) Pub. No.: US 2025/0220206 A1
(43) Pub. Date: Jul. 3, 2025

(54) FRAME BUFFER USAGE DURING A DECODING PROCESS

(71) Applicant: V-NOVA INTERNATIONAL LIMITED, London (GB)

(72) Inventor: Obioma OKEHIE, London (GB)

(21) Appl. No.: 18/852,306

(22) PCT Filed: Mar. 30, 2023
(86) PCT No.: PCT/GB2023/050836

§ 371 Date: Sep. 27, 2024

(30) Foreign Application Priority Data
Mar. 31, 2022 (GB) 2204675.9

(51) Int. Cl. H04N 19/423; H04N 19/90

(52) U.S. Cl. CPC H04N 19/423; H04N 19/90

(57) ABSTRACT

There is provided a method of using a frame buffer during a decoding process. The method is performed on a dedicated hardware circuit. The method comprises using a frame buffer to store data representative of a first frame data. The data representative of a first frame data is used when decoding, subsequently, a second frame data. The frame buffer is stored in memory external to the dedicated hardware circuit. The data representative of a first frame data is a set of transformed elements indicative of an extent of spatial correlation in the first frame data. The method compresses the set of transformed elements using a lossless compression technique and sends the compressed set of transformed elements to the frame buffer for retrieval when decoding the second frame data.

### TECHNICAL FIELD

The present application relates to frame buffer usage by a decoder during a decoding process. In particular, but not exclusively, the decoder is configured to decode data signals comprising frames of data. In particular, but not exclusively, the data signals relate to video data. In particular, but not exclusively, the decoder implements low complexity video coding (LCEVC) techniques. In particular, but not exclusively, the decoder is implemented on a dedicated hardware circuit, and the dedicated hardware circuit leverages an external memory in which the frame buffer resides to store data used during the decoding process.

### BACKGROUND

Data is often transmitted from one place to another for use; for example, video or image data may be transmitted from a server or storage medium to a client device for display. The data is often encoded, for ease of transmission and storage. When received, the client device must then decode any encoded data to reconstruct the original signal or an approximation thereof.

In some implementations, a decoder may re-use data previously derived in the decoding process when decoding subsequent data. The previously derived data is stored in a memory (in particular in a “frame buffer”) that can be accessed by the decoder when required, for example when decoding a subsequent frame of data. It is important to ensure that access to the stored data in the frame buffer is quick enough to enable real-time decoding, otherwise an unacceptable bottleneck could occur in the decoding pipeline, and the decoded data would not be presented in time. For example, individual frames of video data must be decoded in time to render a frame of video at the appropriate time to maintain the frame rate. This challenge is increased for relatively high frame resolutions (e.g. at present, 8K) and is further increased for relatively high frame rates (e.g. at present, 60 FPS), or vice versa.

Often, it is desirable to implement a decoder on a dedicated hardware circuit, such as an application specific integrated circuit (ASIC) or a field programmable gate array (FPGA). Typically, the frame buffer is located in a main memory that is external to the dedicated hardware circuit (i.e. “off-chip memory”) because it is relatively expensive to locate memory on a dedicated hardware circuit itself. This arrangement introduces a potential bottleneck into the decoding pipeline as accessing the off-chip memory is relatively slow when compared to accessing on-chip memory. In some applications, especially applications that relate to particularly large amounts of data which push the limits of current hardware processing and storage technologies (e.g. 8K 60 FPS video data), the process of reading and writing data to the off-chip memory may be so slow as to interrupt real-time decoding.

Therefore, there is a need for a technique for managing data at a decoder to prevent undesired delay to a decoding process due to memory access speed limitations in general. There is also a need for a technique for managing data at a decoder to prevent undesired delay to a decoding process due to memory access speed limitations in a particular situation where the decoder is on a dedicated hardware circuit and the frame buffer is on a memory external to the dedicated hardware circuit. There is also a need for a technique that allows for real-time decoding the previously mentioned scenarios. The invention or inventions described in this application attempt to provide a solution, at least partially, to one or more of the above-described needs.

### SUMMARY

According to a first aspect of the invention, there is provided a method of using a frame buffer during a decoding process. The method in this aspect is typically performed on a dedicated hardware circuit, for example, an ASIC, an FPGA, etc. However, the method will find use in other implementations where there is a read/write bottleneck when accessing memory. The method comprises using a frame buffer to store data representative of a first frame data. The data representative of a first frame data is used when processing a second frame data. In a typical implementation, the frame buffer is stored in memory external to the dedicated hardware circuit. The data representative of a first frame data is a set of transformed elements indicative of an extent of spatial correlation in the first frame data. The method compresses the set of transformed elements using a lossless compression technique and sends the compressed set of transformed elements to the frame buffer for retrieval when processing the second frame data.

In this way, the data representative of a first frame may be compressed by a relatively large multiplication, e.g., 100× compression as opposed to typical frame buffer compression techniques which may achieve only 2-3× compression. Data that is indicative of an extent of spatial correlation in the frames of data is relatively sparse when compared to the frame data itself, and when compressed using lossless compression a high degree of compression can be achieved. As such, the time taken for the decoder to write the data representative of a first frame into the external memory and retrieve said data can be significantly reduced. Thus, it less likely for unwanted delays or an interruption of real-time decoding to occur due to slow reading and writing of data to an off-chip memory or the like. In addition, using lossless compression techniques reduces artefacts in the decoded data.

Preferably, the retrieval of the set of transformed elements from the frame buffer comprises performing an inverse lossless compression technique to the compressed set of transformed elements. In this way, the compressed data stored in the external memory may be returned to an uncompressed format that can be used by the decoder during the decoding process.

Preferably, the first frame data comprises a first set of residual elements.

Preferably, the first set of residual elements are based on a difference between a first rendition of a first frame associated with the first frame data at a first level of quality in a tiered hierarchy having multiple levels of quality and a second rendition of the first frame at the first level of quality.

Preferably, the set of transformed elements indicate the extent of spatial correlation between the set of residual elements such that at least one of the set of transformed elements indicates at least one of average, horizontal, vertical and diagonal (AHVD) relationship between neighbouring residual elements in the set of residual elements. In this way, a greater compressibility can be achieved by using data related to AHVD relationship between neighbouring residual elements in the set of residual elements which are sparse and can be significantly compressed. In addition, AVHD data can be processed in parallel leading to fast compression and increased speed of reading and writing data into a memory.

Preferably, the method comprises receiving a first input data. The first input data is indicative of an extent of temporal correlation between the set of transformed elements and a second set of transformed elements.

Preferably, the second set of transformed elements are indicative of an extent of spatial correlation in a second set of residual elements.

Preferably, the second set of residual elements are for reconstructing a rendition of a second frame associated with the second frame data at the first level of quality using data based on a rendition of the second frame at the second level of quality.

Preferably, the second set of residual elements are based on a difference between a first rendition of the second frame at the first level of quality in a tiered hierarchy having multiple levels of quality and a second rendition of the second frame at the first level of quality.

Preferably, the second set of transformed elements indicate the extent of spatial correlation between the plurality of residual elements in the second set of residual elements associated with the second frame such that at least one of the second set of transformed elements indicates at least one of an average, horizontal, vertical and diagonal relationship between neighbouring residual elements in the second set of residual elements.

Preferably, the method comprises combining the first input data with the set of transformed elements to generate the second set of transformed elements.

Preferably, the method comprises performing an inverse transformation operation on the second set of transformed elements to generate the second set of residual elements.

Preferably, the method comprises receiving a second input data. In one example, the second input data is at the second level of quality in the tiered hierarchy. Optionally, the second level being lower than the first level.

Preferably, the method comprises performing an upsampling operation on the second input data to generate a second rendition of the second frame of the video signal at the first level of quality.

Preferably, the method comprises combining the second rendition of the second frame of the video signal and the second set of residual elements to reconstruct the second frame.

Preferably, the first input data comprises a quantised version of a result of a difference between the set of transformed elements and the second set of transformed elements.

Preferably, the set of transformed elements are associated with an array of signal elements in the first frame. The second set of transformed elements are associated with an array of signal elements in the second frame at the same spatial position as the array of signal elements in the first frame.

Preferably, the lossless compression technique comprises two different lossless compression techniques. However, in some implementations it may be useful to use one lossless compression technique or more than two lossless compression techniques.

Preferably, the lossless compression technique comprises at least one of run length encoding and Huffman encoding. However, in some implementations it may be useful to use other types of lossless compression technique for example, range encoding.

Preferably, the lossless compression technique comprises run length encoding followed by Huffman encoding.

In one example, the decoding process is configured to decode a video signal. In a more specific example, the video signal is at least an 8K 60 FPS video signal.

According to a second aspect of the invention, there is provided a decoder apparatus implemented on a dedicated hardware circuit, wherein the decoder apparatus comprises a data communication link for communication with an external memory. The decoder apparatus is configured to perform the method of any preceding statement.

According to a second aspect of the invention, there is provided a computer program comprising instructions which, when executed, cause the decoder apparatus to perform a method according to any previous statement.

### BRIEF DESCRIPTION OF THE DRAWINGS

The invention shall now be described, by way of example only, with reference to the accompanying drawings in which:

FIG. 1 is a block diagram showing an example signal processing system including a hardware module;

FIG. 2 is a schematic diagram showing the hardware module of FIG. 1 in more detail, and also illustrates a process in accordance with an embodiment of the present invention;

FIG. 3 is a schematic diagram of a decoding process in accordance with an embodiment of the present invention;

FIG. 4 is a flow diagram depicting a method of storing and retrieving a frame buffer in accordance with an embodiment of the present invention;

FIG. 5 is a timing diagram depicting a part serial enhancement architecture timing process of decoding input data; and

FIG. 6 is timing diagram depicting a parallel architecture timing process of decoding input data.

### DETAILED DESCRIPTION

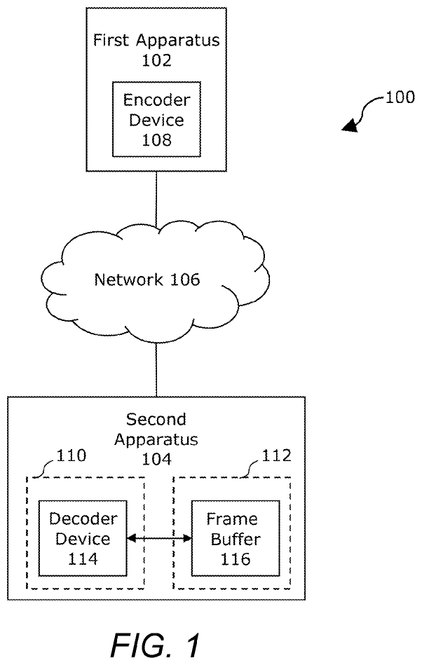

FIG. 1 is a block diagram showing an example of a signal processing system 100 for contextual understanding of this disclosure. The signal processing system 100 is used to process signals. Examples of types of signals include, but are not limited to, video signals, image signals, audio signals, volumetric signals such as those used in medical, scientific or holographic imaging, or other multidimensional signals.

The signal processing system 100 includes a first apparatus 102 and a second apparatus 104. The first apparatus 102 and the second apparatus 104 may have a client-server relationship, with the first apparatus 102 performing the functions of a server device and the second apparatus 104 performing the functions of a client device. The first apparatus 102 and/or second apparatus 104 may comprise one or more components. The components may be implemented in hardware and/or software. The one or more components may be co-located or may be located remotely from each other in the signal processing system 100. Examples of types of apparatus include, but are not limited to, computerised devices, routers, workstations, handheld or laptop computers, tablets, mobile devices, games consoles, smart televisions, set-top boxes, augmented and/or virtual reality headsets etc.

The first apparatus 102 is communicatively coupled to the second apparatus 104 via a data communications network 106. Examples of the data communications network 106 include, but are not limited to, the Internet, a Local Area Network (LAN) and a Wide Area Network (WAN). The first and/or second apparatus 102, 104 may have a wired and/or wireless connection to the data communications network 106.

The first apparatus 102 comprises an encoder device 108. The encoder device 108 is configured to encode a signal by encoding signal data within the signal. The encoder device 108 may perform one or more further functions in addition to encoding signal data. The encoder device 108 may be embodied in various different ways. For example, the encoder device 108 may be embodied in hardware and/or software.

The second apparatus 104 comprises a hardware module 110 and an external memory 112 that is external to the hardware module 110 (i.e., an off-chip memory). In this example, the hardware module 110 is an application specific integrated circuit (ASIC) but other types of hardware circuits or modules may be used, including other types of dedicated hardware circuits such as field programmable gate arrays (FPGAs). The hardware module 110 comprises a decoder device 114.

The encoder device 108 encodes the signal data and transmits the encoded signal data to the decoder device 114 via the data communications network 106. The decoder device 114 decodes the received, encoded signal data and generates decoded signal data. The decoder device 114 is configured to use or output the decoded signal data, or data derived using the decoded signal data. For example, the decoder device 114 may output such data for display on one or more display devices associated with the second apparatus 104. When decoding the encoded signal data, the decoder device 114 is configured to use the external memory 112 for storing a frame buffer 116. The decoder device 114 may perform one or more further functions in addition to decoding encoded signal data.

In some examples, the encoder device 108 transmits to the decoder device 114 a rendition of a signal at a given level of quality and information the decoder device 114 can use to reconstruct a rendition of the signal at one or more higher levels of quality. A rendition of a signal at a given level of quality may be considered to be a representation, version or depiction of data comprised in the signal at the given level of quality. The difference between a rendition of a signal at a given level of quality, wherein the rendition of the signal has been upsampled from a lower level of quality, and the original signal at the given level of quality is known as a residual. The term residual data is known to a person skilled in the field, see for example WO 2018046940 A1. The information the decoder device 114 can use to reconstruct a rendition of the signal at one or more higher levels of quality may be represented by the residual data.

The above concept is known as scalable video coding. An example of scalable video coding is low complexity video coding (LCEVC) which allows a relatively small amount of information to be used for such reconstruction. This may reduce the amount of data transmitted via the data communications network 106. The savings may be particularly relevant where the signal data corresponds to high quality video data.

Alternatively, the encoded signal data may be stored on a storage medium accessible by the second apparatus 104 and/or the decoder device 114 and may not be transmitted across a network.

In some implementations, the decoder device 114 may re-use signal data previously derived in the decoding process when decoding subsequent signal data, for example when there is a temporal connection between elements of the signal data. The previously derived signal data is stored in the frame buffer 116 that can be accessed by the decoder device 114 when required, for example when decoding a subsequent frame of signal data when the signal data is arranged in frames, such as with a video signal. It is important to ensure that access to the stored data in the frame buffer 116 is quick enough to enable real-time decoding, otherwise an unacceptable bottleneck could occur in the decoding pipeline, and the decoded data would not be presented in time. For example, individual frames of video data must be decoded in time to render a frame of video at the appropriate time to maintain the frame rate. This challenge is increased for relatively high frame resolutions (e.g. at present, 8K) and is further increased for relatively high frame rates (e.g. at present, 60 FPS), or vice versa.

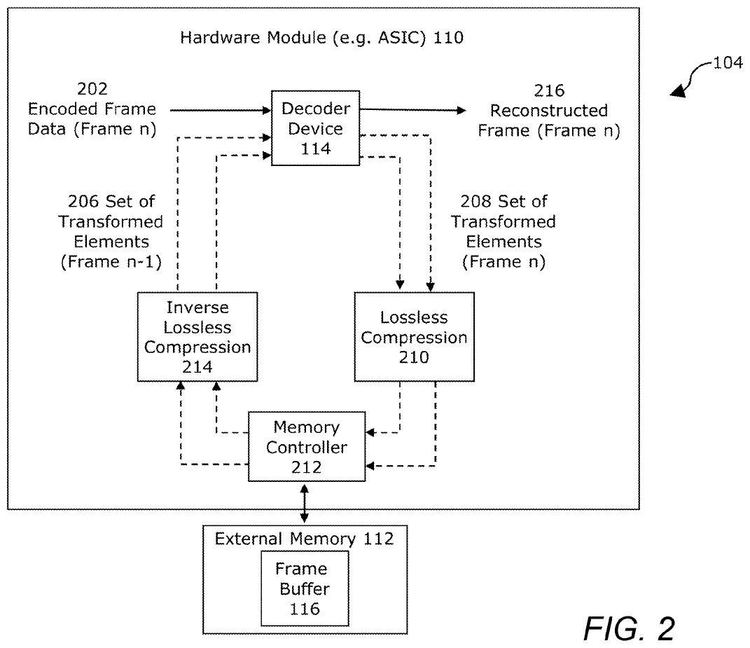

FIG. 2 is a schematic diagram showing the hardware module 110 of FIG. 1 in more detail, and also illustrates a process of storing and retrieving a relevant part of the signal data to and from the frame buffer 116, in accordance with an embodiment of the present invention. The hardware module 110 comprises, in addition to the decoder device 114, a lossless compression module 210, a memory controller 212 and an inverse lossless compression module 214. FIG. 2 also shows the external memory 112 on which is stored the frame buffer 116. The external memory 112 responds to access requests as is known in the art and that would be understood by the skilled person.

In this specific example, during a decoding process, the decoder device 114 receives an encoded frame data (frame n) 202 as part of the encoded signal data, typically from the first apparatus 102 but also possibly from another source such as a computer memory (not shown), and a set of transformed elements (frame n−1) 206 from the frame buffer 116. The decoder device 114 decodes the signal as necessary and uses the encoded frame data (frame n) 202 and the set of transformed elements (frame n−1) 206 to output a reconstructed frame (frame n) 216. Decoder device 114 also outputs a new or updated set of transformed elements (frame n) 208 for storage in the frame buffer 116 to be used in the subsequent frame decoding process. As will be apparent, “n” relates to a frame number in a sequence of frames, and frame n is a current frame being processed and frame n−1 is a previous frame that has already been processed. Frame n is the subsequent frame to frame n−1.

In this example, the encoded frame data (frame n) 202, the set of transformed elements (frame n−1) 206, the set of transformed elements (frame n) 208 and the reconstructed frame n 216 are all associated with a video signal. However, other signals may be processed in this way.

The set of transformed elements (frame n−1) 206 are indicative of an extent of spatial correlation in the corresponding frame data, e.g. the correlation in frame data corresponding to frame n−1. The decoder device 114 uses both the encoded frame data (frame n) 202 and the set of transformed element (frame n−1) 206 to reconstruct frame n and in that process to generate a new set of transformed elements (frame n) for reconstructing a subsequent frame (frame n+1).

The decoder device 114 sends the generated set of transformed elements (frame n) 208 to the lossless compression module 210 to undergo a lossless compression operation. The compressed set of transformed elements (frame n) are then sent to the memory controller 212 to be forwarded to the frame buffer 116 in the external memory 112. The generated set of transformed elements (frame n) 208 overwrite the set of transformed elements (frame n−1) 206 previously stored in the frame buffer 116.

When the decoder device 114 is decoding a current frame (frame n), the memory controller 212 retrieves the compressed set of transformed elements (frame n−1) from the external memory 112. As mentioned above, the sets of transformed elements are stored in the external memory 112 in a compressed format. The memory controller 212 is configured to send the retrieved compressed set of transformed elements (frame n−1) to the inverse lossless compression module 214 to generate the set of transformed elements (frame n−1) 206 in an uncompressed format which are then sent to the decoder device 114 for use in reconstructing a current frame.

The decoder device 114 repeats the above process for a subsequent frame (frame n+1) and retrieves the information in the set of transformed elements (frame n) 208 from the frame buffer 116.

The technique disclosed herein requires previous frame data to be stored to generate future frame data. The technique described herein stores the previous frame data in the form of data that is indicative of an extend of spatial correlation in the previous frame data rather than the raw data itself. Data that is indicative of spatial correlation in the frame data is sparse and can achieve great compressibility in comparison to the raw frame data itself. As such, the compressed data can be sent to an external memory and recovered from the external memory relatively quickly which allows for real-time decoding without interruption.

In this example embodiment, the compression module 210 and inverse compression module 214 are shown to be outside the decoder device 114 itself. However, it is also viable for the compression modules to reside within the decoder device 114.

In this example embodiment, the set of transformed elements (frame n−1) 206 indicate at least one of average, horizontal, vertical and diagonal (AHVD) relationship, or any combination thereof, between neighbouring signal elements in the previous frame data. In this way, a greater compressibility can be achieved by using data related to AHVD data which are sparse and can be significantly compressed. In addition, AVHD data can be processed in parallel leading to fast compression and increased speed of reading and writing data into a memory.

In this example embodiment, the encoded frame data (frame n) 202 is indicative of an extent of temporal correlation between the set of transformed elements (frame n−1) 206 and the set of transformed elements (frame n) 208.

In this example embodiment, the set of transformed elements (frame n) 208 indicate at least one of an average, horizontal, vertical and diagonal relationship, or any combination thereof, between neighbouring signal elements in the current frame data.

In this example embodiment, the encoded frame data (frame n) 202 comprises a quantised version of a result of a difference between the set of transformed elements (frame n−1) 206 and the set of transformed elements (frame n) 208.

In this example embodiment, the set of transformed elements (frame n−1) 206 are associated with an array of signal elements in the previous frame and the set of transformed elements (frame n) 208 are associated with an array of signal elements in the current frame at the same spatial position as the array of signal elements in the previous frame.

In this example embodiment, the lossless compression technique comprises two different lossless compression techniques. Alternatively, the lossless compression technique comprises at least one of run length encoding and Huffman encoding. Alternatively, the lossless compression technique comprises run length encoding followed by Huffman encoding or Huffman encoding followed by run length encoding.

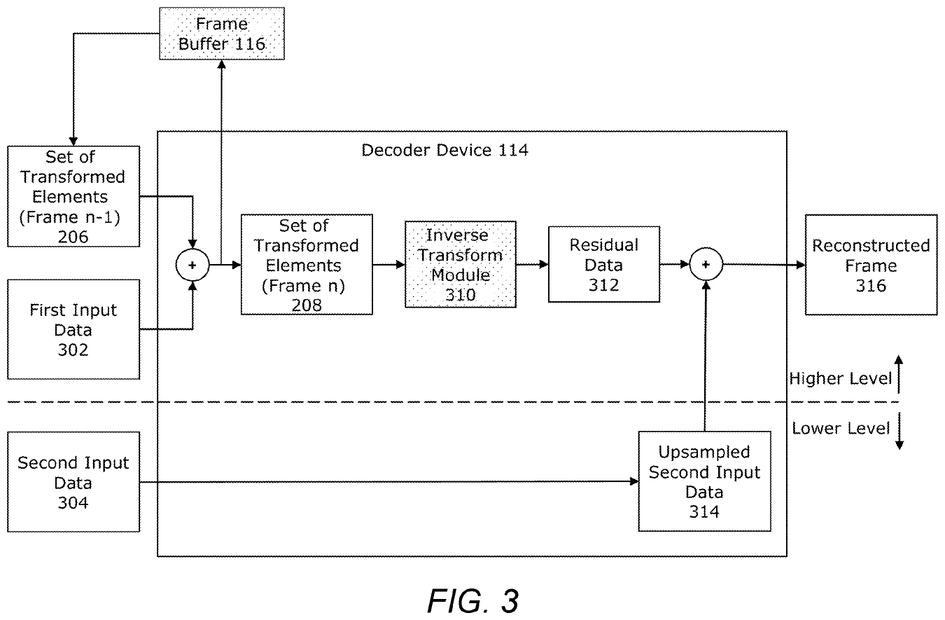

FIG. 3 is a block diagram showing a more specific decoding process in accordance with an embodiment of the present invention. The decoding process shown in FIG. 3 is suitable to be implemented on the hardware module 110 shown in FIG. 2, and like reference signs denote like components and signals for ease of reference. The process shown in FIG. 3 is for a specific type of scalable video coding, although this disclosure has broader application as discussed in relation to FIG. 2. The decoder device 114 receives a first input data 302 and a second input data 304, and outputs a reconstructed frame 316.

In this example embodiment, the first input data 302 and the second input data 304 relate to a video signal. However, the first input data 302 and the second input data 304 may relate to other signals. In this example, the first input data 302 and the second input data 304 are received from an encoder device via network 106 or via a storage medium. In this example embodiment, the first input data is at first level of quality in a tiered hierarchy and the second input data 304 is at a second level of quality in the tiered hierarchy, the second level being lower than the first level. Hence, the first input data 302 corresponds to the higher level in FIG. 3 and the second input data 304 corresponds to the lower level in FIG. 3.

The first input data 302 is useable by the decoder device 114 to reconstruct a signal at the first level of quality. The second input data 304 is useable by the decoder device 114 to reconstruct a signal at the second level of quality when used in the decoder device 114 without the first input data 202.

FIG. 3 shows an example decoding scheme, having two quality layers. However, the concept disclosed in this application is also relevant to alternative schemes having a single quality layer, or more than two quality layers.

When decoding a frame n, the decoder device 114 retrieves the set of transformed elements (frame n−1) 206 stored in the frame buffer 116 as already described with reference to FIG. 2. Also, as described with reference to FIG. 2, the set of transformed elements (frame n−1) 206 undergo a lossless compression operation 210 before they are stored in the frame buffer 116. The frame buffer 116, in this example illustration as well as the illustration in FIG. 2, is located external to the hardware module on which the decoder device 114 resides.

Retrieving the set of transformed elements (frame n−1) 206 from the frame buffer 116 also comprises performing an inverse lossless compression technique 214 to the compressed set of transformed elements (as shown in FIG. 2). The inverse lossless compression technique is the inverse of the lossless compression technique originally used to store the frame n−1 transformed elements in the frame buffer, or otherwise allows the set of transformed elements to be recovered uncompressed.

Using data (i.e. the set of transformed elements) that is indicative of an extent of spatial correlation in the corresponding frame data, e.g. the correlation in frame data corresponding to frame n−1 results in planes of data that are each relatively sparse when compared to the previous frame data itself. When the sparser data is compressed using lossless compression a high degree of compression can be achieved. In this way, the decoder device 114 is able to store the contents of the frame buffer 116 and retrieve the contents of the frame buffer 116, relatively quickly. Thus, it is less likely for unwanted delays or an interruption of real-time decoding to occur. In addition, using lossless compression techniques reduces artefacts in the stored data.

In this example embodiment, the lossless compression technique comprises two different lossless compression techniques. Alternatively, the lossless compression technique comprises at least one of run length encoding and Huffman encoding. Alternatively, the lossless compression technique comprises run length encoding followed by Huffman encoding or Huffman encoding followed by run length encoding.

In more detail in relation to the example of FIG. 3, the first input data 302 is indicative of a relationship between the set of transformed elements (frame n−1) 206 and the set of transformed elements (frame n) 208 such that when the decoder device 114 combines the set of transformed elements (frame n−1) 206 with the first input data 302, the set of transformed elements (frame n) 208 are generated. The generated set of transformed elements (frame n) 208 are sent to the frame buffer 116 in the way described in FIG. 2 to overwrite the set of transformed elements (frame n−1) 206.

In this example embodiment, the indication of the first input data 302 is an indication of an extent of temporal correlation between the set of transformed elements (frame n−1) 206 and the frame n transformed elements 308.

In this example embodiment, the first input data 312 comprises a quantised version of a result of a difference between the set of transformed elements (frame n−1) 206 and the frame n transformed elements 308.

At the inverse transform module 310, the set of transformed elements (frame n) 308 undergo an inverse transformation operation, for example a direct discrete inverse transformation, to generate residual data 312 which is used to create a reconstructed frame 316.

In this example embodiment, the residual data 312 is based on a difference between a first rendition of the frame n at the first level of quality in a tiered hierarchy having multiple levels of quality and the second rendition of the frame n at the first level of quality.

The second input data 304 is upsampled to produce upsampled second input data 314. Residual data 312 and upsampled second input data 314 are combined to produce the reconstructed frame 316. This process of upsampling data and combining said data with residual data is generally known to a skilled person, see for example WO 2018046940 A1. In this example embodiment, the upsampling operation on the second input data 304 generates a second rendition of the frame n of the video signal at the first level of quality.

As will be apparent to the reader, the sets of transformed elements in the context of FIG. 3 act to represent residual data having residual elements used to modify the first input data 302. The residual elements are based on a difference between a first rendition of a specific frame at a first level of quality in a tiered hierarchy having multiple levels of quality and a second rendition of said specific frame at the first level of quality. The sets of transformed elements indicate the extent of spatial correlation between the set of residual elements of the residual data such that the set of transformed elements indicate at least one of average, horizontal, vertical and diagonal (AHVD) relationship, or any combination thereof, between neighbouring residual elements.

In this way, a greater compressibility can be achieved by using data related to AHVD relationship between neighbouring residual elements in the set of transformed elements (frame n−1) 206 which are sparse and can be significantly compressed. In addition, AVHD data can be processed in parallel leading to fast compression and increased speed of reading and writing data into a memory.

In this example embodiment, the set of transformed elements (frame n−1) 306 are associated with an array of signal elements in frame n−1 and the set of transformed elements (frame n) 308 are associated with an array of signal elements in frame n at the same spatial position as the array of signal elements in frame n−1.

The example of FIG. 3 is an LCEVC implementation of the inventive concept. Alternatively, in contexts other than scalable video coding such as LCEVC, the set of transformed elements do not necessarily need to represent residual data, rather the set of transformed elements may represent primary or raw frame data that is an accurate or true representation of an original signal.

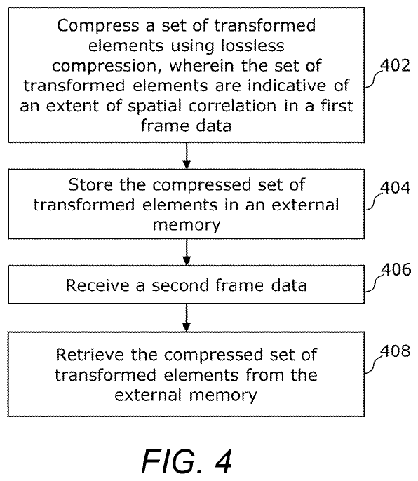

FIG. 4 is a flow diagram depicting a method of storing and retrieving a frame buffer in accordance with an embodiment of the present invention. At step 402, the method comprises compressing a set of transformed elements using lossless compression, wherein the set of transformed elements are indicative of an extent of spatial correlation in a first frame data. At step 404, the method comprises storing the compressed set of transformed elements in an external memory. At step 406, the method comprises receiving a second frame data. At step 408, the method comprises retrieving the compressed set of transformed elements from the external memory.

All the features discussed with respect to FIG. 2 and FIG. 3 that are not shown in FIG. 4 can be optionally added to the method steps of FIG. 4.

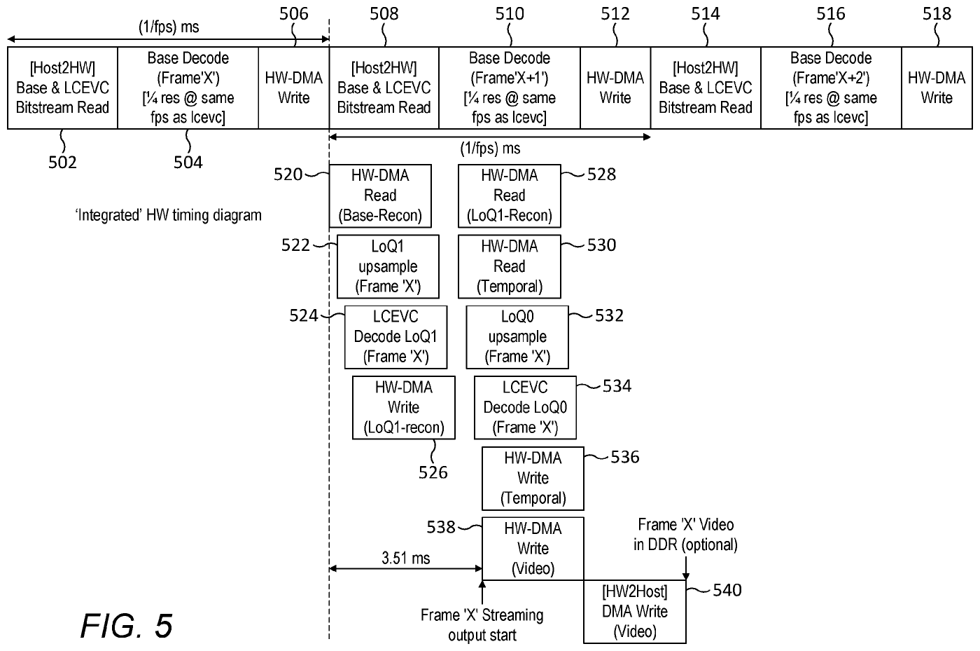

FIG. 5 is a timing diagram depicting a part serial enhancement architecture timing process of decoding an input data stream, in this example a base and LCEVC bitstream comprising a base layer and one or more LCEVC enhancement layers representing frames of picture information. In FIG. 5, there is shown a timing process having three cycles and three frames for decoding, namely Frame X, Frame X+1 and Frame X+2. The first cycle comprises timing blocks 502, 504 and 506 and is for decoding the base layer for Frame X and is also for decoding any enhancement layers for Frame X−1 (not shown). The second cycle comprises timing blocks 508, 510, and 512 and is for decoding the base layer for Frame X+1 and is also for decoding any enhancement layers for Frame X. The third cycle comprises timing blocks 514, 516 and 518 and is for decoding the base layer for Frame X+2 and is also for decoding any enhancement layers for Frame X+1 (not shown). The three cycles will produce decoded frames for Frame X−1, Frame X and Frame X+1, and will produce a base decoded version of Frame X+2.

Each cycle has a time period of 1/fps to complete, where fps is the frame rate in frames per second.

In more detail in relation to the first cycle, at block 502, the base and LCEVC bitstream corresponding to Frame X is read. At second timing block 504, the base layer of Frame X is decoded to create a based decoded Frame X. At block 506, using a HW-DMA (hardware direct memory access) the base decoded Frame X is written to a memory. In this example, frames in the base layer are at quarter the resolution but at the same frame rate as corresponding frames in the LCEVC enhancement layer or layers.

During the second cycle, the above process repeats for Frame X+1. In more detail, at block 508, the base layer is read from the input data stream corresponding to Frame X+1. At block 510, the base layer of frame X+1 is decoded. At block 512, using the HW-DMA the base decoded frame X+1 is written to the memory.

During the third cycle the above process repeats for Frame X+2. In more detail, at block 514, the base layer is read from the input data corresponding to Frame X+2. At block 516, the base layer of Frame X+2 is decoded. At block 518, using the HW-DMA the base decoded Frame X+2 is written to the memory.

In all three cycles described above, during block 502 and equivalent blocks 508 and 514 the necessary LCEVC enhancement layer data needed for the respective cycle is read as described in the following paragraph. For example, block 508 reads the enhancement layer data for Frame X and block 514 reads the enhancement layer data for Frame X−1.

The second cycle shows how each cycle works in more detail. While blocks 508 and 510 are operating to perform a base decoding of Frame X+1, the necessary enhancement data in the LCEVC enhancement layer(s) is decoded and applied to the lower quality data in parallel to create a fully decoded Frame X. At block 520, a HW-DMA reads a base reconstruction of Frame X from the memory as stored during the first cycle at block 506. At block 522, the base reconstruction of Frame X is upsampled to a first level of quality LoQ1. At block 524, the LCEVC enhancement layer data for Frame X at the first level of quality LoQ1 is decoded and applied to the base reconstruction of Frame X to produce a reconstruction at the first level of quality LoQ1. At block 526, using the HW-DMA the reconstruction of Frame X at the first level of quality LoQ1 is written to the memory. The blocks 520, 522, 524 and 526 operate in parallel so that as soon as information relating to processable blocks of data elements or pixels within Frame X are available the following block begins to perform its operations while the current block continues to operate on the remaining processable blocks of data elements or pixels.

After block 526 completes processing, a new parallel set of blocks begins starting with blocks 528 and 530. In more detail, at block 528, the HW-DMA reads the reconstruction of Frame X at the first level quality LoQ1 from the memory. At block 530, the HW-DMA reads temporal predication data from the memory which is used to keep a record of previous enhancement data and so reduce the amount of data signalled in the enhancement layer(s). At block 532, the reconstruction of Frame X at the first level quality LoQ1 is upsampled to produce a version of Frame X at a second level quality LoQ0. At block 534, the LCEVC enhancement layer data of Frame X at level LoQ0 is decoded and applied to the version of Frame X at the second level of quality LoQ0 to produce a reconstruction at the second level of quality. At block 536, using the HW-DMA, temporal prediction data is written to the memory for reuse in the next cycle. At block 538, using the HW-DMA, Frame X at reconstruction level of quality LoQ0 is written to the memory to be part of decoded video output from the decoding process. At this point, the decoded output from the decoding process for Frame X may be streamed. At block 540, the Frame X at reconstruction level of quality LoQ0 is written to a host memory. This step 540 may or may not be included in the system design, depending on the specific requirements of the application. The video data may be stored in Double Data Rate (DDR) memory.

As can be seen from FIG. 5, in this example, the time taken between the reading of the base reconstruction of Frame X from a memory at block 520 and the writing the Frame X at reconstruction level of quality LoQ0 at block 538 is 3.51 ms. Therefore, it takes 3.51 ms for Frame X to be available for streaming output from the start of the reading of the base reconstruction of Frame X. This length of time is due at least partly because block 528 does not start processing data until block 526 is finished, i.e. the writing of the reconstruction of Frame X at the first level of quality LoQ1 to the memory is complete. For this reason, the process of FIG. 5 is referred to as a part serial enhancement architecture timing process.

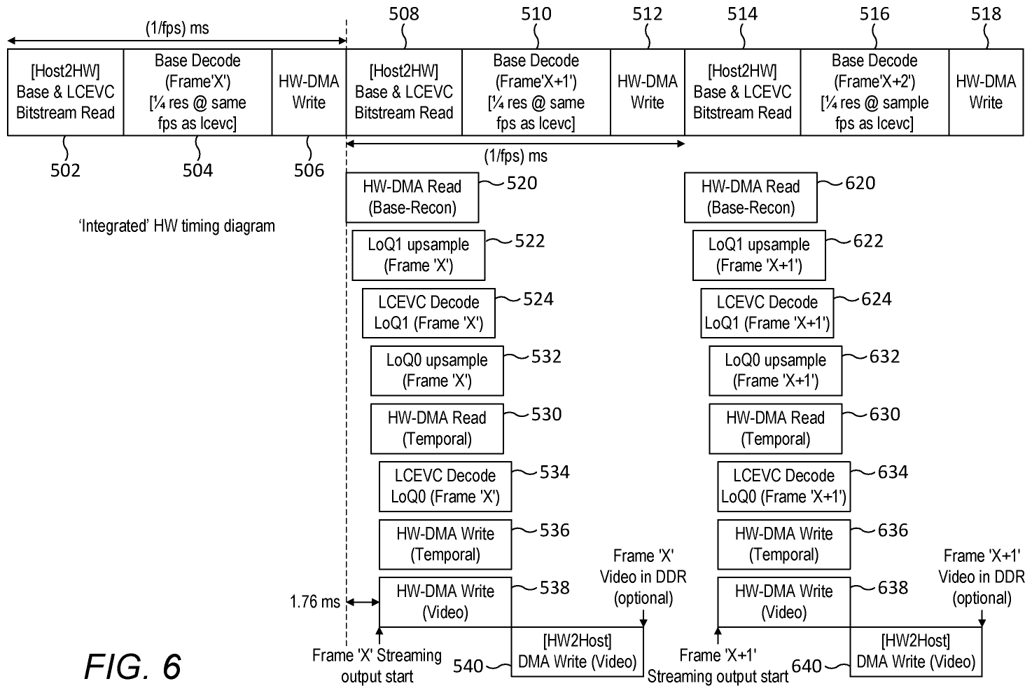

FIG. 6 is timing diagram depicting a parallel architecture timing process of decoding input data. Like reference signs in FIGS. 5 and 6 denote like blocks for ease of reference and are not described further.

Blocks 526 and 528 are not used in FIG. 6. As such, the time taken between the reading of the base reconstruction of Frame X from a memory at block 520 and the writing of the video data at block 538 is reduced to 1.76 ms which is half the time of the serial architecture of FIG. 5. Therefore, it takes 1.76 ms for Frame X streaming output to start from the start of the reading of the base reconstruction of Frame X.

FIG. 6 also shows the process of preparing Frame X+1 streaming output. FIG. 6 shows blocks 620-640 which are the same as blocks 520-540 but in the context of Frame X+1.

Using HW-DMA writes allow for a faster encoding or decoding of video data, by allowing an encoder or a decoder to bypass the CPU, in order to improve performance.

The techniques described herein may be implemented in software or hardware, or may be implemented using a combination of software and hardware. The software may be a computer program comprising instructions which when executed by an apparatus perform the techniques described herein.

The above embodiments are to be understood as illustrative examples. Further embodiments are envisaged. It is to be understood that any feature described in relation to any one embodiment may be used alone or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1-24. (canceled)

25. A method of using a frame buffer during a decoding process, wherein the method is performed on a dedicated hardware circuit, and the method comprises:
using a frame buffer to store data representative of a first frame data, wherein the data representative of the first frame data is used when processing a second frame data;
wherein:
the frame buffer is stored in memory external to the dedicated hardware circuit;
the data representative of a first frame data is a set of transformed elements indicative of an extent of spatial correlation in the first frame data;
the method compresses the set of transformed elements using a lossless compression technique and sends the compressed set of transformed elements to the frame buffer for retrieval when processing the second frame data.

26. The method of claim 25, wherein the retrieval of the set of transformed elements from the frame buffer comprises performing an inverse lossless compression technique to the compressed set of transformed elements.

27. The method of claim 26, wherein the first frame data comprises a first set of residual elements.

28. The method of claim 26, wherein the first set of residual elements are based on a difference between a first rendition of a first frame associated with the first frame data at a first level of quality in a tiered hierarchy having multiple levels of quality and a second rendition of the first frame at the first level of quality.

29. The method of claim 27, wherein, the set of transformed elements indicate the extent of spatial correlation between the first set of residual elements such that the set of transformed elements indicate at least one of average, horizontal, vertical and
diagonal relationship between neighboring residual elements in the set of residual elements.

30. The method of any of claim 27, wherein the method comprises receiving a first input data, wherein the first input data is indicative of an extent of temporal correlation between the set of transformed elements and a second set of transformed elements.

31. The method of claim 30, wherein the second set of transformed elements are indicative of an extent of spatial correlation in a second set of residual elements.

32. The method of claim 31, wherein the second set of residual elements are for reconstructing a rendition of a second frame associated with the second frame data at the first level of quality using data based on a rendition of the second frame at the second level of quality.

33. The method of claim 31, wherein the second set of residual elements are based on a difference between a first rendition of the second frame at the first level of quality in a tiered hierarchy having multiple levels of quality and a second rendition of the second frame at the first level of quality.

34. The method of claim 31, wherein the second set of transformed elements indicate the extent of spatial correlation between the plurality of residual elements in the second set of residual elements associated with the second frame such that the second set of transformed elements indicate at least one of an average, horizontal, vertical and diagonal relationship between neighboring residual elements in the second set of residual elements.

35. The method of claim 30, wherein the method comprises combining the first input data with the set of transformed elements to generate the second set of transformed elements.

36. The method of claim 35, wherein the method comprises performing an inverse transformation operation on the second set of transformed elements to generate the second set of residual elements.

37. The method of claim 36, wherein the method comprises receiving a second input data, wherein the second input data is at the second level of quality in the tiered hierarchy, the second level being lower than the first level.

38. The method of claim 37, wherein the method comprises performing an upsampling operation on the second input data to generate a second rendition of the second frame at the first level of quality.

39. The method of claim 38, wherein the method comprises combining the second rendition of the second frame and the second set of residual elements to reconstruct the second frame.

40. The method of claim 30, wherein the first input data comprises a quantized version of a result of a difference between the set of transformed elements and the second set of transformed elements.

41. The method of claim 30, wherein the set of transformed elements are associated with an array of signal elements in the first frame and wherein the second set of transformed elements are associated with an array of signal elements in the second frame at the same spatial position as the array of signal elements in the first frame.

42. The method of claim 25, wherein the lossless compression technique comprises two different lossless compression techniques.

43. The method of claim 25, wherein the lossless compression technique comprises at least one of run length encoding and Huffman encoding or wherein the lossless compression technique comprises run length encoding followed by Huffman encoding.

44. The method of any preceding claim, wherein the decoding process is configured to decode a video signal, wherein the video signal is at least an 8K 60 FPS video signal.

45. A decoder apparatus implemented as a dedicated hardware circuit, wherein the decoder apparatus comprises a data communication link for communication with an external memory, the decoder apparatus comprising:
a processor;
a non-transitory storage device that stores computer executable instructions that, when executed by the processor, cause the decoder apparatus to:
use a frame buffer to store data representative of a first frame data, wherein the data representative of the first frame data is used when processing a second frame data;
wherein:
the frame buffer is stored in memory external to the dedicated hardware circuit;
the data representative of a first frame data is a set of transformed elements indicative of an extent of spatial correlation in the first frame data;
the decoder apparatus compresses the set of transformed elements using a lossless compression technique and sends the compressed set of transformed elements to the frame buffer for retrieval when processing the second frame data

46. A non-transitory storage device that stores computer executable instructions that, when executed by the processor, cause a decoder apparatus to:
use a frame buffer to store data representative of a first frame data, wherein the data representative of the first frame data is used when processing a second frame data;
wherein:
the frame buffer is stored in memory external to a dedicated hardware circuit;
the data representative of a first frame data is a set of transformed elements indicative of an extent of spatial correlation in the first frame data;
the decoder apparatus compresses the set of transformed elements using a lossless compression technique and sends the compressed set of transformed elements to the frame buffer for retrieval when processing the second frame data.
